(19) United States
(12) Patent Application Publication
(10) Pub. No.: US 2011/0002029 A1
(43) Pub. Date: Jan. 6, 2011

(54) OPTICAL CLOCK

(75) Inventor: Gregor John McDonald, Upton-on-Severn (GB)

Correspondence Address: OLIFF & BERRIDGE, PLC, P.O. BOX 320850, ALEXANDRIA, VA, 22320-4850, US

(73) Assignee: QINETIQ LIMITED, London (GB)

(21) Appl. No.: 12/918,885

(22) PCT Filed: Mar. 9, 2009
(86) PCT No.: PCT/GB2009/000622

§ 371 Date: Aug. 23, 2010

(30) Foreign Application Priority Data
Mar. 10, 2008 (GB) 0804410.9
Mar. 12, 2008 (GB) 0804564.3

(51) Int. Cl. G02F 1/01; H03M 1/00; G04G 3/00; H01S 3/10; H04B 10/18

(52) U.S. Cl. 359/276; 341/137; 372/26

(57) ABSTRACT

An optical clock for generating a series of optical clock pulses, comprises a laser source for generating output having a plurality of spectral components λ₁, λ₂, . . . λ_{N}, an amplitude-modulator arranged to cooperate with the laser source to produce a series of intermediate optical pulses each having the plurality of spectral components, and optical fibre arranged to provide dispersion of each intermediate optical pulse to form a plurality of component pulses each corresponding to a spectral component and to compress each component pulse, the spectral width of each spectral component being sufficient to inhibit stimulated Brillouin scattering (SBS) of the component pulses within the optical fibre. The optical clock may be used for analogue-to-digital conversion of an electrical signal, in which application pulses of respective spectral components are demultiplexed and subsequently detected and digitised in parallel, providing for faster conversion.

The invention relates to optical clocks.

Optical clocks which produce ultra-short optical pulses with low timing jitter are of interest in applications such as high bit-rate optical communication and photonic analogue-to-digital conversion (ADC). In the case of photonic ADC, ultra-short optical clock pulses are required so that an analogue signal can be sampled at a series of discrete times, avoiding integration over a range of signal values each time the analogue signal is sampled. Low timing jitter is desirable because errors in sampling time result in inaccurate conversion of a rapidly changing analogue signal.

Optical clocks having the above characteristics typically comprise modelocked lasers, for example a diode-laser modelocked in an external cavity. Such a device requires significant human intervention in order to set the device up and keep it running in a desired operational state. Such devices are therefore highly unsuited to practical applications outside the laboratory. Clocks based on modelocked fibre-lasers (see for example W. Ng et al, Journal of Lightwave Technology, 22, pp 1953-1961, 1994) provide some degree of physical and operational robustness, however such a device requires a feedback arrangement to compensate for drift in repetition rate resulting from path length changes caused by temperature fluctuations in the surrounding environment. Such clocks are therefore physically complex. Furthermore, modelocked lasers comprise very specialised components, making clocks based on them unsuitable for mass-production. Another problem associated with clocks based on modelocked lasers (including modelocked fibre-lasers) is that adjustment of the repetition rate of the optical clock pulses is complicated as this involves careful adjustment of the laser cavity length.

A first aspect of the invention provides an optical clock for generating a series of optical clock pulses, the optical clock comprising a laser source for generating output having a plurality of spectral components, an amplitude-modulator arranged to cooperate with the laser source to produce a series of intermediate optical pulses each having said plurality of spectral components, and optical fibre arranged to provide dispersion of each intermediate optical pulse to form a plurality of component pulses each corresponding to a spectral component and to compress each component pulse, wherein the spectral width of each spectral component is sufficient to inhibit stimulated Brillouin scattering (SBS) of the component pulses within the optical fibre.

An optical clock of the invention is simple in terms of construction, is robust and may be assembled from readily-available components. Such a clock may operate indefinitely without human intervention. Compression of the component pulses occurs by soliton-effect compression, which includes self phase-modulation (SPM). Stimulated Brillouin scattering (SBS), which typically occurs within optical fibres at peak-powers also associated with SPM, and which can reduce optical power output and stability from the optical fibre, is inhibited as a result of the linewidth of the spectral components of the laser source. Unlike optical clocks based on modelocked lasers, precise alignment of the components of a clock of the invention is not required. Optical clock pulses output from the optical fibre have low timing-jitter and may be as short as 10-15 ps, or shorter, as a result of compression by SPM, or SPM and group velocity dispersion. Optical clock pulses output from the optical fibre may be used directly as optical clock pulses, or they may be manipulated in some way (e.g. pulse-picked) to produce a series of optical clock pulses.

Preferably, the optical clock is arranged to generate a continuous series of optical clock pulses at a repetition rate f_{clock}, the amplitude modulator being arranged to produce the intermediate pulses at a repetition frequency f_{clock}/N, where N is the number of spectral components of the laser source.

The laser source may comprise a laser oscillator arranged for operation on a plurality of longitudinal modes each of which corresponds to a spectral component, and modulating means arranged to produce phase-modulation in the output of the laser oscillator so that the spectral components have a linewidth sufficient to inhibit SBS. The modulating means may be a phase-modulator arranged to directly phase-modulate the output of the laser oscillator. Alternatively, if the laser oscillator is a semiconductor laser oscillator, the modulating means may comprise means arranged to modulate the injection-current of the semiconductor laser.

As an alternative to use of a single laser operating on a plurality of longitudinal modes, the laser source may comprise a plurality of laser oscillators each having an output of a respective output wavelength corresponding to a spectral component, a multiplexer arranged to multiplex outputs of the laser oscillators to produce a multiplexed output, and modulating means arranged to produced phase-modulation in the multiplexed output. The modulating means may comprise a phase-modulator arranged to phase-modulate the multiplexed output, or plural phase-modulators each arranged to phase-modulate the output of a respective laser oscillator prior to multiplexing. Alternatively, if each laser oscillator is semiconductor laser oscillator (e.g. a DFB laser) the modulating means may comprise means for modulating the injection-currents of the semiconductor laser oscillators.

In order to minimise timing-jitter in optical clock pulses of embodiments of the invention which comprise modulating means for producing phase-modulation in the output or outputs of one or more laser oscillators, preferably the modulating means is arranged to provide phase-modulation with a minimum modulation-depth consistent with inhibiting SBS in the optical fibre.

In order to reduce frequency-noise in the repetition frequency f_{clock} of optical clock pulses output from the clock in the range from 10 Hz to f_{clock}/2, and hence make the output optical clock pulses better suited to sampling applications (e.g. photonic ADC), preferably the modulating means is arranged to provide phase-modulation at a frequency equal to half the repetition frequency of the optical clock pulses. In some embodiments, the modulating means is arranged to carry out phase-modulation at a frequency less than half the repetition frequency of compressed component pulses output from the optical fibre, but means are provided to pulse-pick these optical pulses so that optical clock pulses have a repetition frequency equal to twice the frequency of phase-modulation.

The optical fibre may comprise standard telecommunications fibre, or alternating lengths of standard telecommunications fibre and dispersion-shifted fibre, or it may comprise dispersion decreasing fibre.

To reduce the output power required of the laser source, an optical amplifier (e.g. an erbium-doped fibre-amplifier (EDFA)) may be used to amplify the series of intermediate optical pulses prior to soliton-effect compression thereof in the optical fibre. The amount of amplified spontaneous emission entering the optical fibre from the amplifier may be reduced by using a circulator at the end of the optical fibre into which the series of phase-modulated optical pulses is introduced, the circulator being coupled to a Bragg grating having an appropriate grating-pitch.

An optical clock of the invention may be used to digitise an analogue electrical signal by inputting the optical clock pulses to a second amplitude modulator which is arranged to receive the electrical signal to be digitised. The resulting amplitude-modulated clock pulses may then be detected and digitised. Preferably, the resulting amplitude-modulated clock pulses are demultiplexed and pulses of different wavelengths detected and digitised in parallel. This provides faster conversion, or for a given conversion speed, allows use of lower speed and cheaper detection and digitisation electronics for the each of the various wavelengths in the amplitude-modulated optical clock pulses output from the second amplitude modulator.

Another aspect of the invention provides a method of generating a series of optical clock pulses, the method comprising the steps of:

(i) generating output from a laser source, the output having a plurality of spectral components;
(ii) amplitude-modulating the output of the laser source to produce an intermediate series of optical pulses each having said plurality of spectral components; and
(iii) passing the intermediate series of optical pulses through an optical fibre to provide dispersion of each intermediate optical pulse to form a plurality of component pulses each corresponding to a spectral component and to compress each component pulse,
the spectral width of each spectral component being sufficient to inhibit stimulated Brillouin scattering (SBS) of the component pulses within the optical fibre.

Embodiments of the invention are described below by way of example only, and with reference to the accompanying drawings in which:

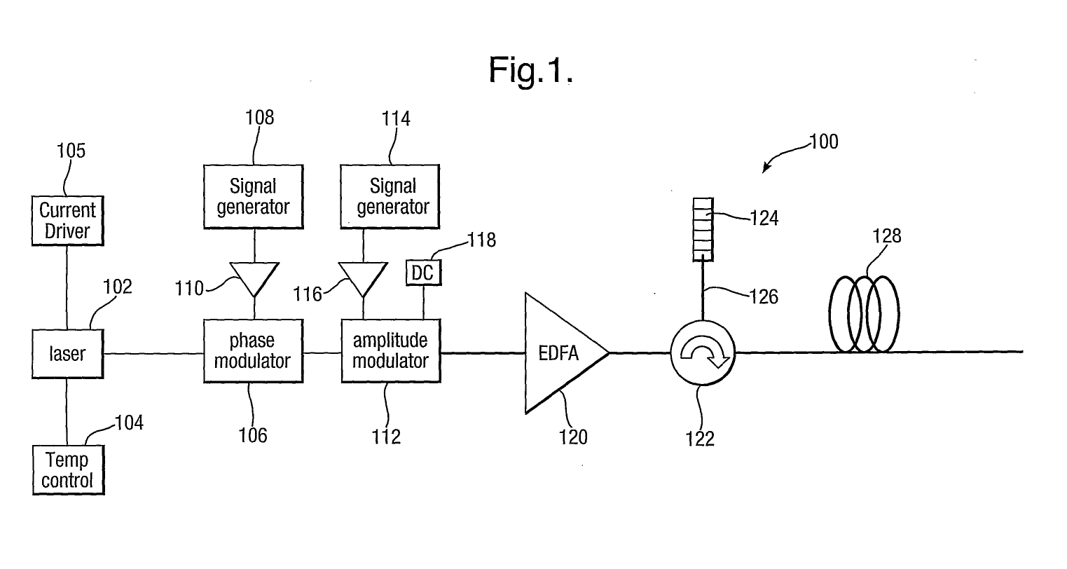

FIG. 1 shows a first example optical clock of the invention;

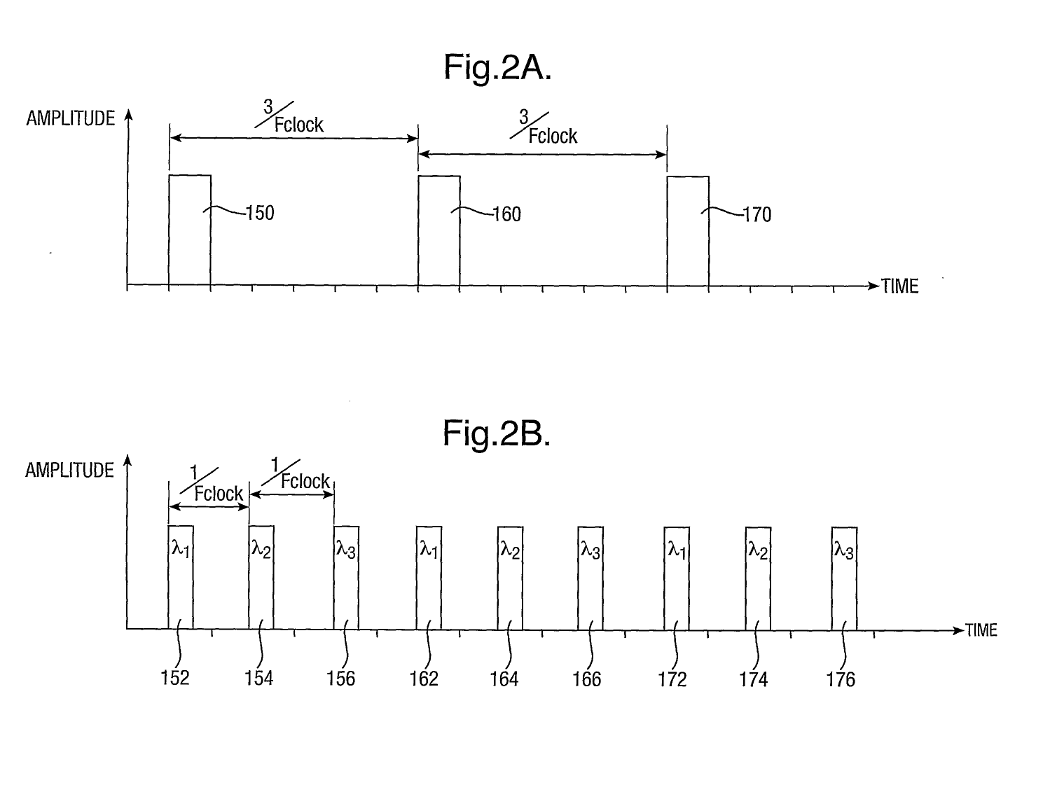

FIGS. 2A & 2B illustrate dispersion and soliton-effect compression of pulses within an optical fibre comprised in the FIG. 1 clock;

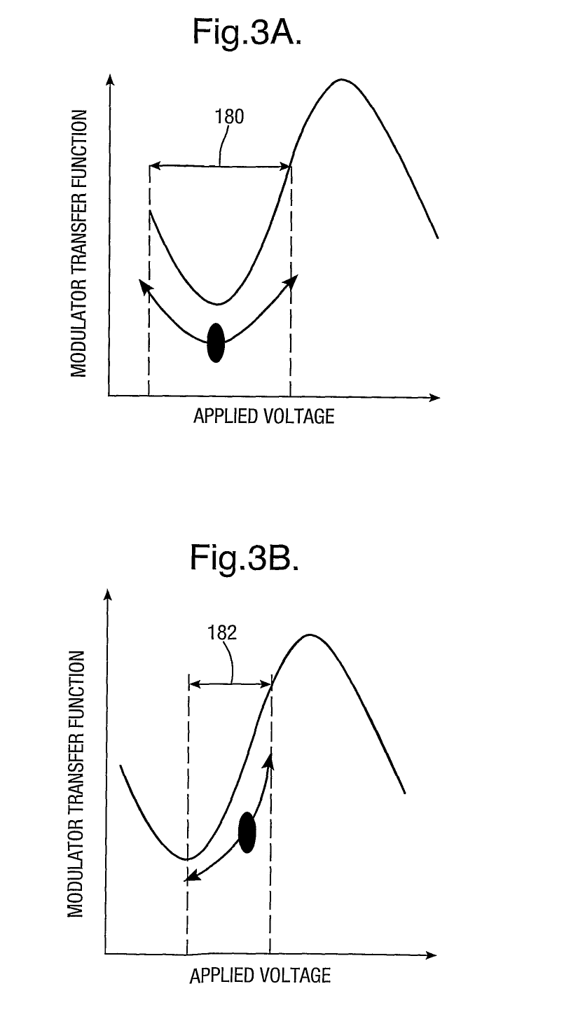

FIGS. 3A & 3B illustrate two modes of operation of the amplitude-modulator of the FIG. 1 clock;

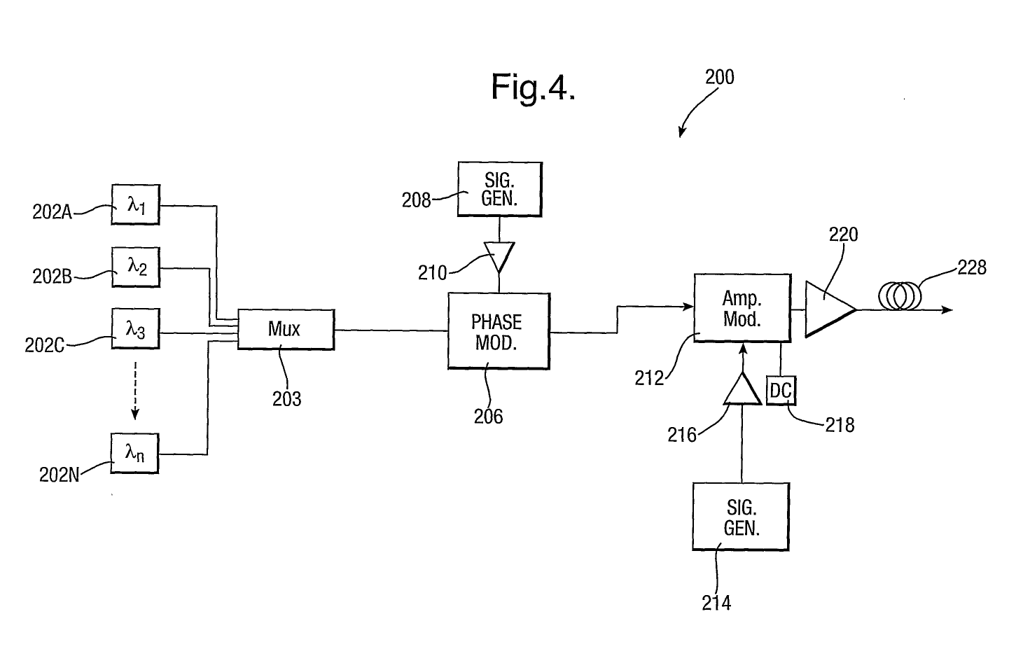

FIG. 4 shows a second example optical clock of the invention; and

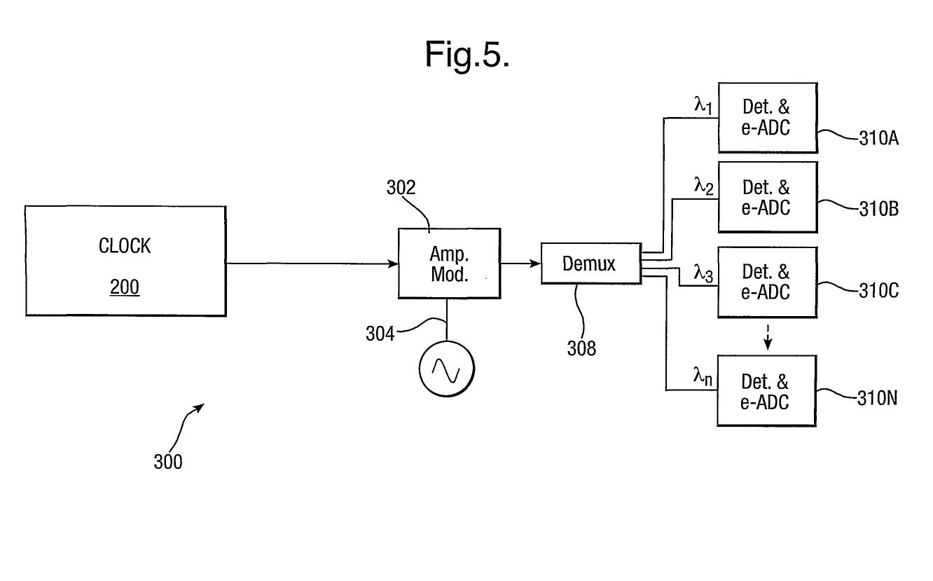

FIG. 5 shows an analogue-to-digital converter of the invention incorporating the optical clock of FIG. 4.

In FIG. 1, an optical clock 100 of the invention comprises a semiconductor laser oscillator 102 arranged to operate on three longitudinal modes λ₁, λ₂, λ₃, each longitudinal mode being a spectral component of the output of the laser 102. The laser 102 is temperature-stabilised by a temperature-controller 104 to stabilise the output wavelengths of the laser 102. Output from the laser 102 passes to a phase-modulator 106 and then to a push/pull-type amplitude-modulator 112. Modulators 106, 112 are standard devices, based on gallium arsenide for example, and are driven by signal generators 108, 114 the output signals of which are amplified by amplifiers 110, 116 before being applied to the modulators 106, 112. Signal generator 114 is an HP® model 83711A. A DC supply 118 provides a DC bias to the amplitude-modulator 112. Optical output from the amplitude-modulator 112 is in the form of an intermediate series of optical pulses each of which comprises the spectral components λ₁, λ₂, λ₃ of the output of the laser 102. Three such intermediate pulses 150, 160, 170 are shown in FIG. 2A.

Each intermediate pulse is amplified by an erbium-doped fibre-amplifier (EDFA) 120 and input to an optical fibre 128 via a circulator 122 which is coupled to a Bragg grating 124 by a short length of optical fibre 126. The optical fibre 128 is a 25.2 km length of SMF-28 fibre. The circulator 122 and Bragg grating 124 act to reduce amplified spontaneous emission within the optical fibre 128 originating from the EDFA 120.

The wavelength spacing of the longitudinal modes λ₁, λ₂, λ₃ of the laser 102, the length and dispersion characteristics of the optical fibre 128 and the operating frequency of the signal generator 114 are such that the intermediate pulses undergo dispersion into their spectral components on passing through the optical fibre 128. The component pulses also experience soliton-effect compression (including self-phase modulation, SPM) on passing through the optical fibre 128. For example, as shown in FIG. 2B, the intermediate pulses 150, 160, 170 of FIG. 2A disperse to form a group of nine compressed component pulses 152, 154, 156, 162, 164, 166, 172, 174, 176. Since there are three spectral components λ₁, λ₂, λ₃ in the output of the laser 102 (i.e. N=3), the amplitude-modulator 112 is arranged to operate at a frequency which is ⅓ of the frequency f_{clock} of the optical clock pulses.

The compressed component pulses output from the optical fibre 128 may have a duration of 10-15 ps, although shorter durations are possible. The EDFA 120 is adjusted so that the intermediate optical pulses have sufficient peak power to allow SPM.

It is desirable that the depth of the phase-modulation is no greater than is required to reduce SBS within the optical fibre 128 because larger modulation depths tend to increase timing-jitter in the optical clock pulses output from the clock 100.

The DC supply 118 is adjusted to keep the modulator 112 biased at null in order to avoid positive and negative chirping of successive optical pulses output from the amplitude-modulator 112, which would result in non-identical successive intermediate optical pulses.

FIG. 3A shows the operative portion of the modulation transfer function of the amplitude modulator 112 as a function of voltage applied by the DC supply 118. In the clock 100 of FIG. 1 the bias voltage applied by the DC voltage supply 118 is adjusted so that a portion 180 of the function is utilised. Referring to FIG. 3B, the DC supply 118 may alternatively be adjusted to bias the amplitude modulator 112 so that a portion 182 of the transfer function is used: in this case the repetition frequency of the intermediate pulses output by the modulator 112 is equal to the frequency of the signal applied by the signal generator 114 via the amplifier 110.

The operating frequency of the phase-modulator 106 is equal to half the repetition frequency of the compressed component pulses output from the optical fibre 128 and the compressed component pulses output from the optical fibre 128 are the optical clock pulses. In an alternative embodiment, the operating frequency of the phase-modulator 106 is less than half the repetition frequency of the compressed component pulses output from the optical fibre 128, but pulse-picking means is provided to eliminate certain pulses from the compressed component pulses output from the optical fibre 128 to produce the series of optical clock pulses at a repetition rate equal to twice the frequency of the phase-modulation. The pulse-picking means could be a step-recovery diode or an amplitude modulator, for example.

The clock 100 has the advantage that any drift in the output wavelengths of the laser 102 affects all the longitudinal modes equally, so that the repetition rate of the optical clock pulses is not affected.

FIG. 4 shows another optical clock 200 of the invention, comprising a plurality of lasers 202A, 202B, 202C, . . . 202N each having an output of a respective wavelength λ₁, λ₂, . . . λₙ, a multiplexer 203, phase- and amplitude-modulators 206, 212 and associated signal generators 208, 214, amplifiers 210, 216, a DC supply 218, an EDFA 120 and an optical fibre 128.

Outputs from lasers 202 are multiplexed by the multiplexer 203 to produce a (single) multiplexed output having the spectral components λ₁, λ₂, . . . λₙ which is passed to the phase-modulator 206 and then to the amplitude-modulator 212 to produce a series of intermediate optical pulses. The intermediate optical pulses are amplified by the EDFA 220 and input to the optical fibre 228 which provides dispersion of the intermediate optical pulses into component pulses, and soliton-effect compression of the component pulses. The clock 200 outputs a continuous series of optical clock pulses. The phase-modulator 206 produces a phase-modulation in the output of the multiplexer 203 which is of sufficient depth to inhibit SBS of the component pulses within the optical fibre 228. The EDFA 220 is provided to ensure that the intermediate optical pulses have sufficient amplitude to give rise to SPM within the optical fibre 228.

The phase-modulator 206 is operated such that the frequency of phase-modulation is at least half the repetition frequency of compressed component pulses output from the fibre 228, so that these pulses are the optical clock pulses. Alternatively the modulator 206 may be operated such that the frequency of phase-modulation is less than half the repetition frequency of the compressed component pulses output from the optical fibre 228 and pulse-picking means provided to eliminate certain of the compressed component pulses output from the fibre 228 to produce the series of optical clock pulses.

Referring to FIG. 5, an analogue-to digital converter 300 of the invention comprises the optical clock 200 of FIG. 4, a second amplitude-modulator 302, a demultiplexer 302 and plural electronic detection and digitisation units 310A, 310B, . . . 310N, each corresponding to a spectral component λ₁, λ₂, . . . λₙ in the output of the optical clock 200.

An electrical signal to be digitised is provided to the amplitude-modulator 202 via an input 304. The output of the amplitude-modulator 302 comprises a series of optical pulses in which pulses of given wavelength have an amplitude corresponding to the amplitude of the input signal at a particular time or times. The spectral components in the output of the amplitude-modulator 302 are demultiplexed by the demultiplexer 308 and passed to respective electronic detection and digitisation units 310A, 310B, 310C, . . . 310N. By providing for the various spectral components to be detected and digitised in parallel, lower speed electronics may be employed in the units 310 than would be the case if the pulses output from the modulator 302 were to be directly detected and digitised without demultiplexing.

1. An optical clock for generating a series of optical clock pulses, the optical clock comprising a laser source for generating output having a plurality of spectral components, an amplitude-modulator arranged to cooperate with the laser source to produce a series of intermediate optical pulses each having said plurality of spectral components, and optical fibre arranged to provide dispersion of each intermediate optical pulse to form a plurality of component pulses each corresponding to a spectral component and to compress each component pulse, wherein the spectral width of each spectral component is sufficient to inhibit stimulated Brillouin scattering (SBS) of the component pulses within the optical fibre.

2. An optical clock according to claim 1 wherein the optical clock is arranged to generate a continuous series of optical clock pulses at a repetition frequency fclock and wherein amplitude modulator is arranged to produce the intermediate optical pulses at a repetition rate fclock/N, where N is the number of spectral components.

3. An optical clock according to claim 1 wherein the laser source comprises a laser oscillator arranged for operation on a plurality of longitudinal modes each corresponding to a spectral component and modulating means arranged to cooperate with the laser oscillator to produce phase-modulation in the output of the laser oscillator.

4. (canceled)

5. An optical clock according to claim 3 wherein the laser oscillator is a semiconductor laser oscillator and the modulating means comprises means arranged to modulate the injection-current of the semiconductor laser oscillator.

6. An optical clock according to claim 1 wherein the laser source comprises a plurality of laser oscillators each having an output of a respective output wavelength corresponding to a spectral component, a multiplexer arranged to multiplex outputs of the laser oscillators to produce a multiplexed output, and modulating means arranged to produced phase-modulation in the multiplexed output.

7. An optical clock according to claim 6 wherein the modulating means comprises one of the following: a phase-modulator arranged to phase-modulate the multiplexed output; plural phase-modulators each arranged to phase-modulate the output of a respective laser oscillator.

8. (canceled)

9. An optical clock according to claim 6 wherein each laser oscillator is a semiconductor laser oscillator and the modulating means comprises means for modulating the injection-currents of the semiconductor laser oscillators.

10-14. (canceled)

15. A clock according to claim 1 wherein the optical fibre comprises one of: alternating lengths of standard telecommunications fibre and dispersion-shifted fibre; a dispersion decreasing fibre.

16. (canceled)

17. A clock according to claim 1 and further comprising an optical amplifier arranged to amplify the series of intermediate optical pulses prior to input thereof to an end of the optical fibre.

18. A clock according to claim 17 further comprising a circulator positioned at said end of the optical fibre and a Bragg grating optically coupled to the circulator, and wherein the circulator and the Bragg grating are arranged to reduce amplified spontaneous emission within the optical fibre.

19. A method of generating a series of optical clock pulses, the method comprising the steps of:
(i) generating output from a laser source, the output having a plurality of spectral components;
(ii) amplitude-modulating the output of the laser source to produce an intermediate series of optical pulses each having said plurality of spectral components; and
(iii) passing the series of intermediate optical pulses through an optical fibre to provide dispersion of each optical pulse to form a plurality of component pulses each corresponding to a spectral component and to compress each component pulse,
the spectral width of each spectral component being sufficient to inhibit stimulated Brillouin scattering (SBS) of the component pulses within the optical fibre.

20. A method according to claim 19 wherein step (ii) is carried out by amplitude-modulating the output of the laser source at a frequency fclock/N to produce a continuous series of optical clock pulses having a repetition rate fclock.

21. A method according to claim 19 wherein step (i) is carried out by generating output from a laser oscillator arranged to operate on a plurality of longitudinal modes and producing phase-modulation in the output of the laser oscillator.

22. (canceled)

23. (canceled)

24. A method according to claim 19 wherein step (i) is carried out by generating output from a plurality of laser oscillators each having an output of a respective output wavelength, multiplexing the outputs of the laser oscillators to provide a multiplexed output, and producing phase-modulation in the multiplexed output.

25. (canceled)

26. (canceled)

27. A method according to claim 24 wherein the laser oscillators are semiconductor laser oscillators and the step of producing phase-modulation in the multiplexed output is carried out by modulating the injection currents of the semiconductor laser oscillators.

28. A method according to claim 21 wherein the phase-modulation is produced with a minimum modulation depth consistent with inhibiting SBS within the optical fibre.

29. A method according to claim 21 wherein the phase-modulation is provided with a modulation frequency equal to half the repetition frequency of the optical clock pulses.

30. A method according to claim 29 wherein the phase-modulation is provided with a modulation frequency which is less than half the repetition frequency of compressed component pulses output from the fibre and wherein the method further comprises the step of pulse-picking compressed component pulses output from the optical fibre to produce the series of optical clock pulses such that the repetition frequency thereof is equal to twice the frequency of the phase-modulation.

31. (canceled)

32. An analogue-to-digital converter comprising an optical clock according to claim 2 and a second amplitude-modulator arranged to modulate the amplitude of optical clock pulses received from the clock in response to input of an analogue signal to be digitised.

33. An analogue-to-digital converter according to claim 32 further comprising a demultiplexer arranged to demultiplex output from the second amplitude modulator to produce a plurality of spectral components and means arranged to detect and digitise each spectral component.

34-39. (canceled)
